(19) United States
(12) Patent Application Publication
(10) Pub. No.: US 2008/0175033 A1
(43) Pub. Date: Jul. 24, 2008

(54) METHOD AND SYSTEM FOR IMPROVING DOMAIN STABILITY IN A FERROELECTRIC MEDIA

(75) Inventors: Li-Peng Wang, San Jose, CA (US); Donald Edward Adams, Pleasanton, CA (US); Qing Ma, San Jose, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 11/625,187

(22) Filed: Jan. 19, 2007

(51) Int. Cl. G11C 11/22

(52) U.S. Cl. 365/145

(57) ABSTRACT

A method of recording information on a media including a ferroelectric recording layer comprises writing the information by forming one or more domains within the ferroelectric recording layer, the one or more domains having a spontaneous polarization, and arranging the one or more domains in a pattern that improves a stability of the one or more domains.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

This invention relates to high density data storage.

### BACKGROUND

Software developers continue to develop steadily more data intensive products, such as ever-more sophisticated, and graphic intensive applications and operating systems. As a result, higher capacity memory, both volatile and non-volatile, has been in persistent demand. Add to this demand the need for capacity for storing data and media files, and the confluence of personal computing and consumer electronics in the form of portable media players (PMPs), personal digital assistants (PDAs), sophisticated mobile phones, and laptop computers, which has placed a premium on compactness and reliability.

Nearly every personal computer and server in use today contains one or more hard disk drives (HDD) for permanently storing frequently accessed data. Every mainframe and supercomputer is connected to hundreds of HDDs Consumer electronic goods ranging from camcorders to TiVo® use HDDs. While HDDs store large amounts of data, they consume a great deal of power, require long access times, and require “spin-up” time on power-up. Further, HDD technology based on magnetic recording technology is approaching a physical limitation due to super paramagnetic phenomenon. Data storage devices based on scanning probe microscopy (SPM) techniques have been studied as future ultra-high density (>1Tbit/in 2) systems. Ferroelectric thin films have been proposed as promising recording media by controlling the spontaneous polarization directions corresponding to the data bits. However, uncontrolled switching of the polarization direction of a data bit can undesirably result in ferroelectric thin films as data bit density increase.

### BRIEF DESCRIPTION OF THE DRAWINGS

Further details of the present invention are explained with the help of the attached drawings in which:

FIG. 1: FIG. 1A is a perspective representation of a crystal of a ferroelectric material having a polarization; FIG. 1B is a side representation of the crystal of FIG. 1A.

FIG. 2; FIG. 2A is a schematic representation of a probe arranged over a ferroelectric layer for polarizing a portion of the ferroelectric layer thereby storing information; FIG. 2B is a simplified, idealized energy diagram illustrating the polarization states of the ferroelectric material.

FIG. 3: FIG. 3A is a simplified, hypothetical energy diagram illustrating the polarization states of a ferroelectric material; FIG. 3B is an exemplary pattern for achieving a minified total energy for the ferroelectric material having the hypothetic energy diagram of FIG. 3A.

FIG. 4: FIG. 4A is a simplified, hypothetical energy diagram illustrating the polarization states of another ferroelectric material; FIG. 4B is an exemplary pattern for achieving a minified total energy for the ferroelectric material having the hypothetic energy diagram of FIG. 4A.

FIG. 5: FIG. 5A is a simplified approximation of a density of domains representing a data bit of one of a “1” and a “0” for two adjacent blocks; FIG 5B is a simplified approximation of a density of domains having one of a first spontaneous polarization and a second spontaneous polarization.

FIG. 6 is a representation of a background pattern disposed within a ferroelectric recording layer having getter regions for attracting charged particles.

### DETAILED DESCRIPTION

Ferroelectrics are members of a group of dielectrics that exhibit spontaneous polarization—i.e., polarization in the absence of an electric field. Ferroelectrics are the dielectric analogue of ferromagnetic materials, which may display permanent magnetic behavior. Permanent electric dipoles exist in ferroelectric materials. One common ferroelectric material is lead zirconate titanate (Pb[ZrₓTi₋ₓ]O₃ 0<x<1, also referred to herein as PZT). PZT is a ceramic perovskite material that has a spontaneous polarization which can be reversed in the presence of an electric field. PZT can be doped with either acceptor dopants, which create oxygen (anion) vacancies, or donor dopants, which create metal (cation) vacancies and facilitate domain wall motion in the material. In general, acceptor doping creates hard PZT while donor doping creates soft PZT. In hard PZT, domain wall motion is pinned by impurities thereby lowering the polarization losses in the material relative to soft PZT, but at the expense of a reduced piezoelectric constant.

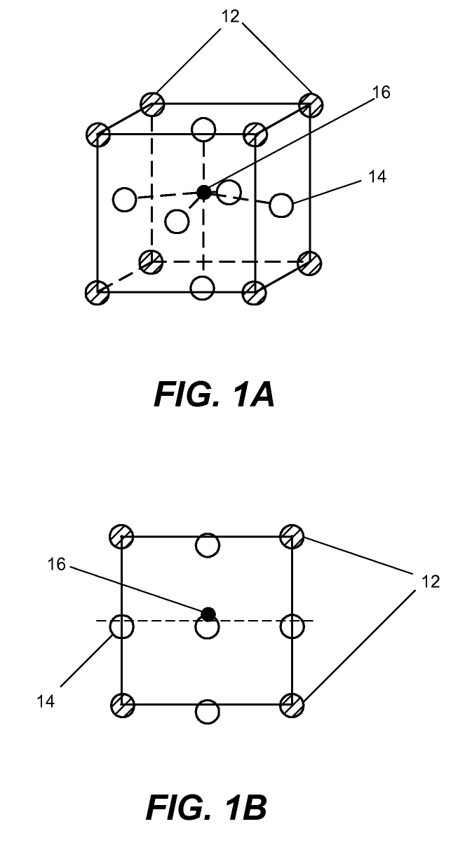

Referring to FIGS. 1A and 1B, a crystal of one of form of PZT, lead titanate (PbTiO₃) is shown. The spontaneous polarization is a consequence of the positioning of the Pb²⁺, Ti⁴⁺, and 0²⁻ ions within the unit cell 10. The Pb²⁺ ions 12 are located at the corners of the unit cell 10, which is of tetragonal symmetry (a cube that has been elongated slightly in one direction). The dipole moment results from the relative displacements of the 0²⁻ and Ti⁴⁺ ions 14,16 from their symmetrical positions. The 0²⁻ ions 14 are located near, but slightly below, the centers of each of the six faces, whereas the Ti⁴⁺ ion 16 is displaces upward from the unit cell 10 center. A permanent ionic dipole moment is associated with the unit cell 10. When lead titanate is heated above its ferroelectric Curie temperature, the unit cell 10 becomes cubic, and the ions assume symmetric positions.

Ferroelectric films have been proposed as promising recording media, with a bit state corresponding to a spontaneous polarization direction of the media, wherein the spontaneous polarization direction is controllable by way of application of an electric field. Ferroelectric films can achieve ultra high bit recording density because the thickness of a 180° domain wall in ferroelectric material is in the range of a few lattices (1-2 nm). However, it has been recognized that maintaining stability of the spontaneous polarization of the media may be problematic, limiting use of the media in memory devices.

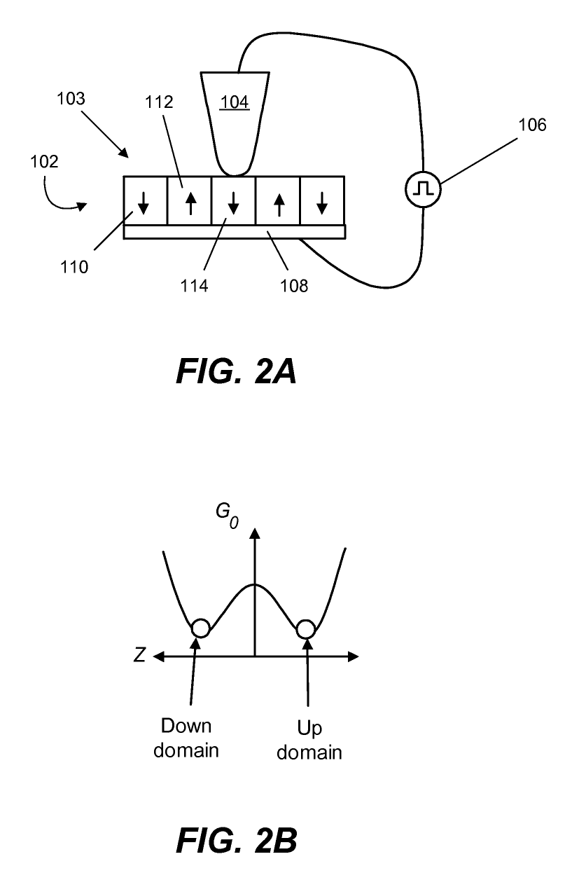

Referring to FIG. 2A, a schematic representation of a probe-storage device is shown comprising a contract probe tip 104 (referred to hereafter as a tip) contacting a surface of a media 102 including a ferroelectric layer 103. The ferroelectric layer 103 includes domains having dipoles 110,112 of alternating orientation. As can be seen, the media 102 has an asymmetric electrical structure, with the ferroelectric layer 103 disposed over a conductive bottom electrode 108. The tip 104 acts as a top electrode when contacting the surface of the media 102, forming a circuit including a portion 114 of the ferroelectric layer 103. A current or voltage source 106 can apply a pulse or other waveform to affect a polarization of the portion 114. However, the surface area of the media 102 in contact with the tip 104 relative to the surface area accessible to the tip 104 is very small at any given time; therefore the media 102 is more accurately approximated as having no top electrode. In addition to affecting the electrical characteristics of the media, the asymmetric structure subjects the ferroelectric layer to film stresses during manufacturing which can affect the ferroelectric properties of the ferroelectric layer. Thus, an asymmetric structure can exacerbate instability of the polarization of domains in the ferroelectric layer.

A system is stable, in a macropscopic sense, when the characteristics of the system do not change with time but persist indefinitely. The stability of a system can be approached if the free energy of the system is at a minimum for a given combination of temperature, pressure and composition. The free energy of a system comprising a media including a ferroelectric layer can be approximated by equation:

G=G_{O}+U

wherein Gₒis a part of the free-energy attributable to a non-zero polarization, and U is a part of the free-energy that is not related to the polarization, and which can be substantially attributed to depolarization energy.

The depolarization energy, U, is negligible where the polarization is small;; however, the polarization of perovskite ferroelectric crystals such as PZT is relatively large. A ferroelectric layer comprising a single domain can result in a large depolarization field. The depolarization field can be expressed by the equation:

$${U}_{depolarization} = \frac{{ɛ}^{*} \cdot d \cdot {P}_{0}^{2} \cdot V}{t}$$

wherein ε* is the effective permittivity, Pₒ is the polarization, V is the domain, d is the domain width, and t is the domain thickness. The depolarization energy is reduced by breaking the ferroelectric layer into domains of different polarization, which consequently results in domain walls having domain wall energy U_{wall} that contribute to the free energy of the system so that the free energy of the system is approximated by equation:

G=Gₒ+U_{wall}+U_{depolarization}

The domain wall energy U_{wall} can be expressed by the equation

$${U}_{wall} = ( \frac{σ}{d} ) \times V$$

wherein σ is the domain energy per area.

FIG. 2B is a hypothetical energy diagram of a domain of a ferroelectric layer exhibiting ideal behavior so that the domain of the ferroelectric layer is electrically balanced. The hypothetical energy diagram plots energy, G, as a function of polarization. The minimum energy of the domain can be achieved with positive or negative polarization. Ideally, the up and down domains are symmetrical and no screening charges are present to reduce the depolarization energy, U. In such an ideal situation, the domain size can be calculated to be most stable at the size of

$$d = \sqrt{\frac{σ \cdot t}{{ɛ}^{*} \cdot {P}_{0}^{2}}}$$

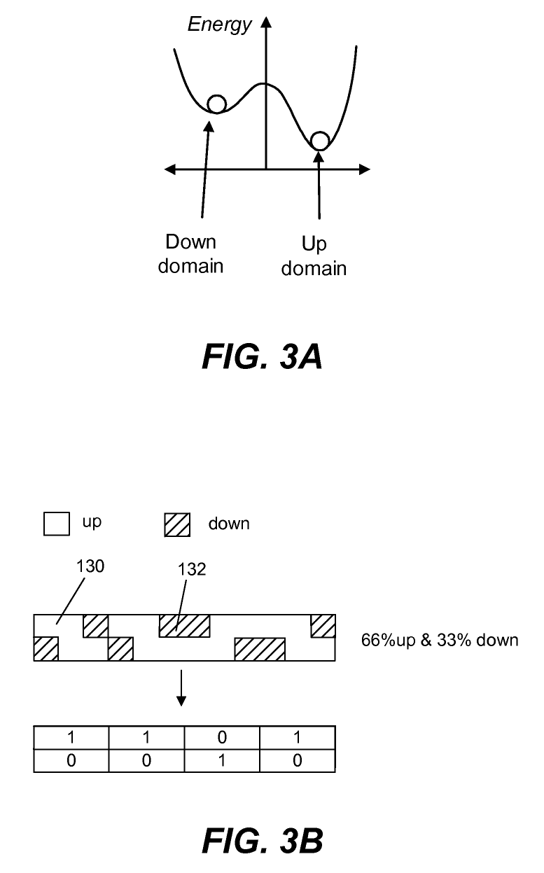

However, where the media has an asymmetric structure, a hypothetical energy diagram of a domain of a ferroelectric layer plotting energy, G, as function of polarization is asymmetric and can resemble the hypothetical energy diagram of FIG. 3A. The actual asymmetry may or may not be accurately reflected by the hypothetical energy domain of FIG. 3A, and can depend of the ferroelectric material used, thickness of the ferroelectric layer, a stress gradient of the ferroelectric layer, and/or other factors. Furthermore, surface charges develop on a least a portion of the ferroelectric layer, and the ferroelectric layer likely includes film defects, such as point defects, linear defects, interfacial defects, and/or boundaries, etc.

The asymmetric relationship of polarization energy and ferroelectric-to-paraelectric transition energy can result in undesirable influences of neighboring domains on one another. For example, where an up domain has a relative lower ferroelectric-to-paraelectric transition energy comparable to a down domain, the up domain can be said to be more stable than the down domain for a given domain size. If the up domain and down domain is formed having an identical size, the more stable up domain can flip the polarization of a portion of the down domain to the polarization of the up domain. The up domain can influence the down domain to expand in size and consequently reduce the down domain in size. This interaction can halt where equilibrium is reached as wall energy of the down domain increases as a result of decreasing domain size. However, it is possible that the entire down domain can be flipped by the neighboring up domain, resulting in lost information.

Embodiments of media and methods in accordance with the present invention can be applied to improve stability of domain polarization in ferroelectric-based probe storage devices, thereby improving data retention. It should be noted that in some contexts, domain can refer to a discrete unit such as a data bit comprising material having non-uniform dipole orientation. However, as used herein, domain refers to a volume of a ferroelectric material having uniform dipole orientation and defined by domain walls. As used herein, a data bit refers to a discrete unit of information and can comprise one or more domains.

In an embodiment, a media and method of improving data retention for ferroelectric-based probe storage devices can comprise arranging domains within a media to obtain a macroscopically minified free energy. Domains can be arranged in groups of two or more domains, a group representing a data bit. The number of domains grouped together to form a data bit can depend on the energy characteristics of the media and the screening charges formed on the surface of the media. For example, for a media having energy characteristics as reflected in the energy diagram of FIG. 3A, a ferroelectric-to-paraelectric transition energy for a down domain is substantially lower than a ferroelectric-to-paraelectric transition energy for an up domain. The up domain is therefore more stable than the down domain, where the two domains are similarly sized. To achiever an approximately symmetrical free energy of a data bit, the data bit can comprise two domain grouped together. In the above example, one of a “1” and a “0” can comprise an up domain followed by a down domain and the other of the “1” and the “0” can comprise a down domain followed by an up domain. The up domain can be substantially larger than the down domain. For example, referring to FIG. 3B, a block of data bits is shown recorded on a media as groups of up domains 130 and down domains 132. Each up domain is roughly twice the size of a down domain. The smaller down domain has a larger contribution of wall energy to the total energy of the domain, resulting in a minified total energy that improves stability of both the up domain and the down domain. Each domain will further be affected by screening charges that may collect on the surface of the domain, and can affect the relative size of the up domain and the down domain within a group. In the example of FIG. 3B, the group is a ratio of 66% up domain and 33% down domain taking into account all affects on the total energy of the system. Two adjacent tracks including a “1101” and a “0010” data pattern are recorded on the media. The first track includes four data bits arranged from left to right in an up-down domain sequence to represent a “1” and a down-up domain sequence to represent a “0”.

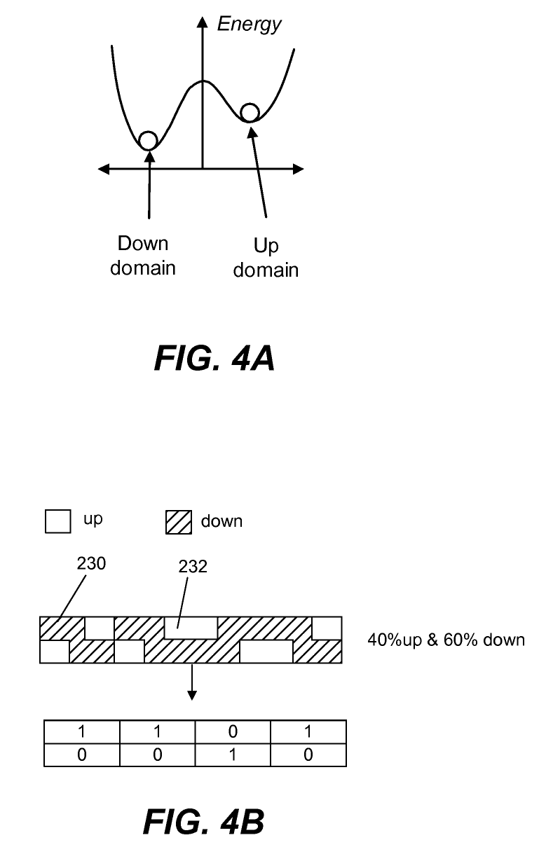

Grouping of domains can be adjusted to suit the energy diagram of the ferroelectric layer of a media, which as noted above can depend on domain thickness, domain width, properties of the ferroelectric material, and other parameters. For example, if a media has a hypothetical energy diagram as shown in FIG. 4A, a ferroelectric-to-paraelectric transition energy for an up domain is lower than a ferroelectric-to-paraelectric transition energy for a down domain. The up domain is therefore less stable than the down domain, where the two domains are similarly sized. To achieve a minified total energy, the up domain can be larger than the down domain. For example, referring to FIG. 4B, a block of data bits is shown recorded on a media as groups of up domains 230 and down domains 232. The group is a ratio of 40% up domain and 60% down domain taking in to account all affects on the total energy of the system. Two adjacent tracks including “1101” and “0010” data patterns are recorded on the media. The first track includes four groups arranged from left to right in an up-down domain sequence to represent a “0” and a down-up domain sequence to represent a “1”. Still other media can have energy diagrams having still different asymmetry. Domains can be sized to achieve a desired ratio within the data bit generally.

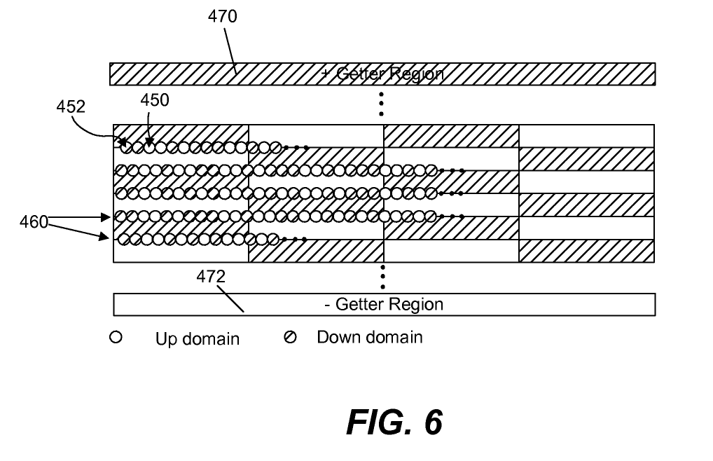

As will be appreciated upon reflecting on the current teachings, an adjacent track (also referred to herein as flanking track) can influence a minimum free energy (and therefore stability) of the track to which it is adjacent, just as domains adjacent within a track can influence a stability of one or both of the domains. Tracks (and domains within tracks) can be written to achieve a desired free energy to result in a desired stability across tacks. In alternative embodiments adjacent tracks can be spaced to reduce instability across adjacent tracks. Alternatively, as shown in FIG. 6, boundaries between larger domains can be modulated to generally improve a stability of the media, and can enable information to be encoded as domains and as run-length limited (RLL) code along the boundaries.

Identifying data bits as groupings of an up domain with a down domain can further controllably limit undesirable arrangements of domains across a track. For example, where a track comprises in part a string of data bits “00000001111111,” the grouping of up and down domains allows recovery of a clock signal, despite a long run of “0” data bits and a long run of “1” data bits. Across track arrangement of data bits can further improve stability. For example, some embodiments of coding schemes can arrange data bits so that the smaller of the up domain and the down domain is not positioned adjacent to more than one identically polarized domain in the tow adjacent tracks.

Grouping of domains can be adjusted to suit a combination of the energy diagram of a media and general screening charges to account for total free energy. The free energy characteristics of a down domain relative to an up domain cannot be easily calculated. However, the ratio of up domains to down domains and an approximation of general screening charges and defects can be experimentally determined for providing a free energy for relatively stable domains at given conditions, wherein the conditions can include ferroelectric considerations and environmental conditions, such as thermal effects. To experimentally determine a desired ratio, up and down domains having different ratios can be written to the media for certain media conditions (e.g., screening ratio, ferroelectric layer thickness, degree of asymmetry). Temperature-accelerated testing can be performed on the media, and a comparison drawn of the ratios of up and down domains to judge the desired ratio (i.e., the most stable and/or most preferred ratio).

In some embodiments, stability of domains can be further improved by arranging data bits to provide a desired balance of data bit states.

In alternative embodiments, a data bit can comprise a single domain. For example, a “0” can be represented by one of an up domain and a down domain and a “1” can be represented by the other of the up domain and the down domain. The data bits can be coded to best approximate a stable ratio of up domains to down domains. Software can be employed to keep track of the arrangement of data. Such schemes are know in the art for ensuring clock recovery for data streams. A useful scheme can group blocks of data using an algorithm to achieve an arrangement that achieves a ratio criterion approaching a minified total energy of the system (e.g., 66:33, 40:60).

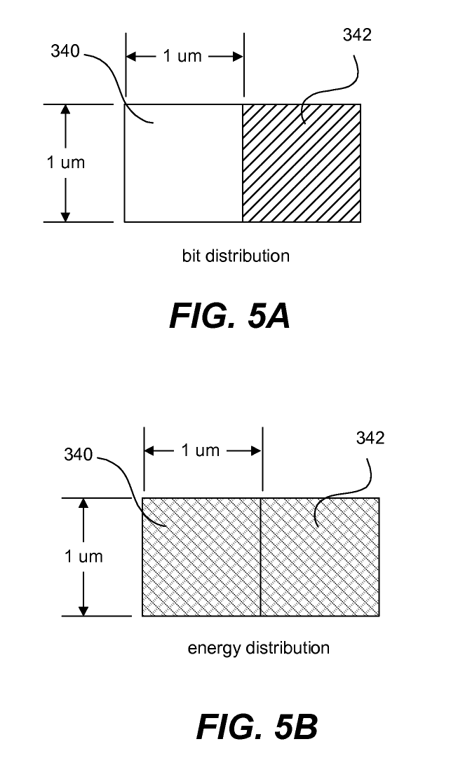

In still further embodiments, data bits can be represented by a single domain, thereby increasing maximum density. To achieve a minified total energy, a media can be divided into sectors. Referring to FIGS. 5A and 5B, in an embodiment, a sector can comprise a first black 340 of data complemented by a second block 342 of data. Data arranged within the first block 340 can be identified as a “1” if a domain is an up domain and a “0” if a domain is a down domain, while data arranged in the second block 342 can be identified as a “0” if a domain is an up domain and a “1”if a domain is a down domain. Assume for the purpose of example, that a volume of information to be stored within the sector includes approximately 50% “1”s and 50% “0”s, and that the desired ratio of domains to achieve a minified total energy is 60% up and 40% down. The data can be scrambled so that 60% of “1” data bits are coded in the first block 340, while 40% of “1” data bits are coded in the second block 342. The total energy of the first block 340 should approximate the total energy of the second block 342, having a ratio of up domains to down domains approximating 60-40 in both the first block 340 and the second block 342 and a ratio approximating of “1” bits to “0” bits approximating 50-50. Data within the first block 340 and second block 342 can be arranged without preference to a coding algorithm provided that a desired ratio of up domains and down domains is achieved within the blocks.

A minimum possible sector size can depend on the characteristics of the ferroelectric layer. As instability of one of the up domains and down domains becomes more problematic, it may be desired that sector size be relatively small. As shown in FIGS. 5A and 5B, a sector comprising two blocks sized 1 μm by 1 μm is contemplated. A single block can therefore include 1600 domains (data bits), where a domain includes a pitch of 25 nm. However, in other embodiments a sector can be larger or smaller as required by the ferroelectric layer.

In still other embodiments, coding techniques can be applied to scramble data within a single block or multiple blocks to achieve information streams that result in a desired ratio of up domains to down domains. Data can be scrambled to assure that each bit is independent, or equally likely, within a channel. Scrambling can avoid continuous worst case patterns within the channel. In combination with an RLL code, scrambling allows shaping of the spatial and temporal spectrums to achieve improvements in data retention. An RLL code can force run length constraints with substantial certainty, thereby improving retention. Thus RLL code can be used with ferroelectric media to improve retention at very high densities. Such coding techniques can further take advantage of error correction code (ECC) applied when scrambling data to be written to a block. ECC is applied to meet density and reliability requirements.

In still further embodiments, a background pattern of polarization can be applied to the media, over which information can be coded. The background pattern can be devised so that the background provides stability, reducing the influence of neighboring bit. For example, as shown in FIG. 6 a background pattern is written either during manufacturing by transferring a pattern of ferroelectric polarization, or by writing domains having ferroelectric polarization by way of one or more tips. Run length limited code, for example, can then be written as up domains 450 and down domains 452 in tracks 460 arranged over transition regions of the background pattern. The background pattern can reduce an influence of screening charges, improving a signal detected by a tip moving over the domains 450,452 written in the tracks. The background pattern can be further devised to incorporate some position and timing information, for example to use in coarse alignment.

As shown in FIG. 6, a background pattern could further comprise one or more getter regions. Getters can be incorporated into the background pattern, for example at the periphery of the background pattern, or at prescribed locations over the pattern. A series of getters can optionally be arranged based on a calculation accounting for format efficiency, estimated migration of charged particles within a package, etc. Charged particles introduced into a package from the environment can be at least partly collected by the getters, which can exert an attractive force on the stray charged particles. Reducing or mitigating an overall screening charge on the ferroelectric layer can improve a signal measured or detected by a tip. Such a feature can further improve a lifetime of the media by resisting degradation by a build-up of screening charges on the ferroelectric layer.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A method of recording information on a media including a ferroelectric recording layer, the method comprising:
writing the information by forming one or more domains within the ferroelectric recording layer, the one or more domains having a spontaneous polarization; and
arranging the one or more domains in a pattern that improves a stability of the one or more domains.

2. The method of claim 1, wherein arranging the one or more domains further includes:
associating a data bit with a group including two domains, the two domains having opposite spontaneous polarization.

3. The method of claim 2, wherein the two domains are sized according to the spontaneous polarization of the two domains.

4. The method of claim 1, wherein arranging the one or more domains further includes:
associating a “0” data bit with a domain having a first spontaneous polarization in a first block and a second spontaneous polarization in a second block;
associating a “1” data bit with a domain having a second spontaneous polarization in a first block and a first spontaneous polarization in a second block; and
arranging information within the first and second block so that domains having the first spontaneous polarization occupy a larger volume within the first and second blocks than domains having the second spontaneous polarization.

5. The method of claim 1, further comprising:
scrambling the information so that the information includes “1” data bits and “0” data bits having a desired proportion substantially similar to a desired proportion of a first spontaneous polarization and a second polarization.

6. A media for recording information in data storage device, the media comprising:
a ferroelectric layer; and
a plurality of domains formed within the ferroelectric layer, each of the plurality of domains having one of a first spontaneous polarization and a second spontaneous polarization;
wherein the plurality of domains are arranged in a pattern having a proportion of first spontaneous polarization and second polarization that improves a stability of the plurality of domains.

7. The media of claim 6, wherein:
a data bit is represented by a group including two domains, the two domains having opposite spontaneous polarization.

8. The media of claim 7, wherein the two domains are sized according to the proportion of first spontaneous polarization and second spontaneous polarization that improves a stability of the data bit.

9. The media of claim 6, further comprising:
a getter region disposed in the ferroelectric layer having one of a first spontaneous polarization and a second spontaneous polarization.

10. The media of claim 6, further comprising:
a plurality of getter regions disposed in the ferroelectric layer, the plurality of getter regions being arranged in a pattern;
each of the plurality of getter regions having one of a first spontaneous polarization and a second spontaneous polarization.

11. The media of claim 10, wherein the pattern is applied based on a determination of minimum surface area of the media at a desired degree of affectivity in attracting to charged particles.

12. A media for recording information in data storage device, the media comprising:
a ferroelectric layer; and
a background pattern disposed within the ferroelectric layer, the background pattern comprising a plurality of regions having one of a first spontaneous polarization and a second spontaneous polarization symmetrically positioned so that each region is adjacent to regions having opposite spontaneous polarization.

13. The media of claim 12, further comprising:
a getter region disposed in the ferroelectric layer having one of a first spontaneous polarization and a second spontaneous polarization.

14. The media of claim 12, further comprising:
a plurality of getter regions disposed in the ferroelectric layer, the plurality of getter regions being arranged in a pattern;
each of the plurality of getter regions having one of a first spontaneous polarization and a second spontaneous polarization.

15. The media of claim 14, wherein the pattern is applied based on a determination of minimum surface area of the media at a desired degree of affectivity in attracting to charged particles.

16. A method of recording information on a media including a ferroelectric recording layer, the method comprising:
writing a background pattern to the ferroelectric recording layer, the background pattern comprising a plurality of regions having one of a first spontaneous polarization and a second spontaneous polarization symmetrically positioned so that each region is adjacent to regions having opposite spontaneous polarization; and
writing the information by forming one or more domains within the ferroelectric recording layer so that the one or more domains straddle two or more regions of the background pattern, the one or more domains having a spontaneous polarization.

17. The method of claim 16, further comprising associating a data bit with a group including two domains, the two domains having opposite spontaneous polarization.

18. The method of claim 17, wherein the two domains are sized according to the spontaneous polarization of the two domains.

19. The method of claim 16, further comprising:
associating a “0” data bit with a domain having a first spontaneous polarization in a first block and a second spontaneous polarization in a second block;
associating a “1” data bit with a domain having a second spontaneous polarization in a fist block and a first spontaneous polarization in a second block; and
arranging information within the first and second block so that domains having the first spontaneous polarization occupy a larger volume within the first and second blocks than domains having the second spontaneous polarization.

20. The method of claim 16, further comprising:
scrambling the information so that the information includes “1” data bits and “0” data bits having a desired proportion substantially similar to a desired proportion of a first spontaneous polarization and a second polarization.
